(19) United States
(12) Patent Application Publication
(10) Pub. No.: US 2018/0282860 A1
(43) Pub. Date: Oct. 4, 2018

(54) HOLDING ARRANGEMENT FOR HOLDING A SUBSTRATE DURING SUBSTRATE PROCESSING IN A VACUUM PROCESSING CHAMBER, CARRIER FOR SUPPORTING A SUBSTRATE IN A VACUUM PROCESSING CHAMBER, AND METHOD FOR HOLDING A SUBSTRATE

(71) Applicants: Simon LAU, Alzenau (DE); Applied Materials, Inc., Santa Clara, CA (US)

(72) Inventor: Simon LAU, Alzenau (DE)

(21) Appl. No.: 15/766,341

(22) PCT Filed: Dec. 7, 2015
(86) PCT No.: PCT/EP2015/078887

§ 371 Date: Apr. 5, 2018

(51) Int. Cl. C23C 14/50; C23C 14/00; B65G 15/58; B65G 15/42

(52) U.S. Cl. CPC C23C 14/50; B65G 15/42; B65G 15/58; C23C 14/0036

(57) ABSTRACT

The present disclosure provides a holding arrangement for holding a substrate during substrate processing in a vacuum processing chamber. The holding arrangement includes a flexible device having one or more sections, wherein the one or more sections are provided in a first operation condition to have a first portion, a second portion and a curved portion, wherein the curved portion is provided between the first portion and the second portion, wherein the first portion has a surface configured to face the substrate, and wherein the first portion and the second portion are moveable with respect to each other, and an adhesive is provided on the surface of the first portion.

### FIELD

Embodiments of the present disclosure relate to a holding arrangement for holding a substrate during substrate processing in a vacuum processing chamber, a carrier for supporting a substrate in a vacuum processing chamber, and a method for holding a substrate. Embodiments of the present disclosure particularly relate to a holding arrangement, a carrier and a method for holding a substrate during a deposition process, such as a sputter deposition process.

### BACKGROUND

Techniques for layer deposition on a substrate include, for example, thermal evaporation, chemical vapor deposition (CVD) and physical vapor deposition (PVD) such as sputtering deposition. A sputter deposition process can be used to deposit a material layer on the substrate, such as a layer of an insulating material. During the sputter deposition process, a target having a target material to be deposited on the substrate is bombarded with ions generated in a plasma region to dislodge atoms of the target material from a surface of the target. The dislodged atoms can form the material layer on the substrate. In a reactive sputter deposition process, the dislodged atoms can react with a gas in the plasma region, for example, nitrogen or oxygen, to form an oxide, a nitride or an oxinitride of the target material on the substrate.

Coated materials can be used in several applications and in several technical fields. For instance, coated materials may be used in the field of microelectronics, such as for generating semiconductor devices. Also, substrates for displays can be coated using a PVD process. Further applications include insulating panels, organic light emitting diode (OLED) panels, substrates with thin film transistors (TFTs), color filters or the like.

The tendency toward larger and also thinner substrates can result in bulging of the substrates due to stress applied to the substrate, e.g., during a deposition process. Support systems which hold a substrate during a deposition process introduce bulging on the substrate, e.g., due to forces that push the substrate edge towards the center of the substrate. Bulging can, in turn, cause problems due to the increasing likelihood of breakage. Accordingly, there is a need to reduce bulging and to support bigger and thinner substrates without damage or breakage.

In view of the above, new holding arrangements for holding a substrate during substrate processing in a vacuum processing chamber, carriers for supporting a substrate in a vacuum processing chamber, and methods for holding a substrate, that overcome at least some of the problems in the art, are beneficial.

### SUMMARY

In light of the above, a holding arrangement for holding a substrate during substrate processing in a vacuum processing chamber, a carrier for supporting a substrate in a vacuum processing chamber, and a method for holding a substrate are provided. Further aspects, benefits, and features of the present disclosure are apparent from the claims, the description, and the accompanying drawings.

According to an aspect of the present disclosure, a holding arrangement for holding a substrate during substrate processing in a vacuum processing chamber is provided. The holding arrangement includes a flexible device having one or more sections, wherein the one or more sections are provided in a first operation condition to have a first portion, a second portion and a curved portion, wherein the curved portion is provided between the first portion and the second portion, wherein the first portion has a surface configured to face the substrate, and wherein the first portion and the second portion are moveable with respect to each other, and an adhesive provided on the surface of the first portion.

According to another aspect of the present disclosure, a carrier for supporting a substrate in a vacuum processing chamber is provided. The carrier includes a carrier body, and one or more holding arrangements, wherein the one or more holding arrangements are mounted on the carrier body. The holding arrangement includes a flexible device having one or more sections, wherein the one or more sections are provided in a first operation condition to have a first portion, a second portion and a curved portion, wherein the curved portion is provided between the first portion and the second portion, wherein the first portion has a surface configured to face the substrate, and wherein the first portion and the second portion are moveable with respect to each other, and an adhesive provided on the surface of the first portion.

According to a further aspect of the present disclosure, a carrier for supporting a substrate in a vacuum processing chamber is provided. The carrier includes at least one flexible device at least partially covered with an adhesive for removably attaching the flexible device to the substrate.

According to an aspect of the present disclosure, a method for holding a substrate is provided. The method includes performing a first rolling motion of a flexible device of a holding arrangement around a rotational axis parallel to a substrate surface to bring an adhesive on a first portion of the flexible device in contact with the substrate surface.

According to another aspect of the present disclosure, a method for holding a substrate is provided. The method includes providing a carrier comprising at least one flexible device at least partially covered with an adhesive, attaching the substrate to the carrier by attaching the adhesive to the substrate, moving the carrier with the substrate through a vacuum processing chamber, and detaching the substrate from the carrier by peeling the adhesive off the substrate.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of a holding arrangement for holding a substrate during substrate processing in a vacuum processing chamber according to embodiments described herein;

FIG. 2 shows a schematic view of a holding arrangement for holding a substrate during substrate processing in a vacuum processing chamber according to further embodiments described herein;

FIG. 3 shows a schematic view of yet another holding arrangement for holding a substrate during substrate processing in a vacuum processing chamber according to embodiments described herein;

FIG. 4 shows a schematic view of a holding arrangement for holding a substrate during substrate processing in a vacuum processing chamber according to yet further embodiments described herein;

FIG. 5 shows a schematic view of a holding arrangement for holding a substrate during substrate processing in a vacuum processing chamber according to further embodiments described herein;

FIG. 6 shows a schematic view of a holding arrangement for holding a substrate during substrate processing in a vacuum processing chamber according to yet further embodiments described herein;

FIG. 7A shows a schematic plan view of a carrier for supporting a substrate in a vacuum processing chamber according to embodiments described herein;

FIGS. 7B and C show cross-sectional side views of the carrier of FIG. 7A;

FIGS. 8A, B and C show schematic views of a holding arrangement for holding a substrate during substrate processing in a vacuum processing chamber according to further embodiments described herein;

FIG. 9 shows a schematic view of a deposition system according to embodiments described herein; and

FIG. 10 shows a flow chart of a method for holding a substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The tendency to larger and also thinner substrates can result in bulging of the substrates due to stress applied to the substrate, e.g., during a deposition process. Support systems such as clamps which hold a substrate during a deposition process introduce bulging on the substrate, e.g., due to forces that push the substrate edge towards the center of the substrate. Bulging can, in turn, cause problems due to the increased likelihood of breakage.

The present disclosure uses a flexible device to “roll” the adhesive onto (first rolling motion) and off (second rolling motion) of the substrate. In particular, the flexible device rolls the adhesive onto the substrate surface in the first rolling motion to hold the substrate and rolls the adhesive off of the substrate surface in the second rolling motion to release the substrate. In some implementations, the motion for detaching the adhesive from the substrate can be referred to as “peeling” or a “peeling motion”. During the detaching, the rolling motion or peeling motion provides a pulling force or shear force with a vector that is non-parallel with respect to the substrate surface. The adhesive can be detached from the substrate surface with reduced mechanical stress. Damage or breakage of the substrate can be prevented. Further, the adhesive can reduce or even avoid a bulging when holding the substrate, e.g., a bulging due to forces that may push the substrate edge towards the center of the substrate. In particular, the embodiments of the present disclosure can hold bigger and thinner substrates without damage or breakage.

The embodiments described herein can be utilized for evaporation on large area substrates, e.g., for display manufacturing. Specifically, the substrates or carriers, for which the structures and methods according to embodiments described herein are provided, are large area substrates. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The term “substrate” as used herein shall embrace inflexible substrates, e.g., plates, and flexible substrates such as a web or a foil. As an example, the substrate can have a thickness of less than 1 mm, specifically less than 0.7 mm, and more specifically less than 50 μm. As an example, the substrate can have a thickness in a range of 0.3 mm to 0.7 mm. According to some embodiments, the substrate can be made from any material suitable for material deposition. For instance, the substrate can be made from a material selected from the group consisting of glass (for instance soda-lime glass, borosilicate glass etc.), metal, polymer, ceramic, compound materials, carbon fiber materials, mica or any other material or combination of materials which can be coated by a deposition process.

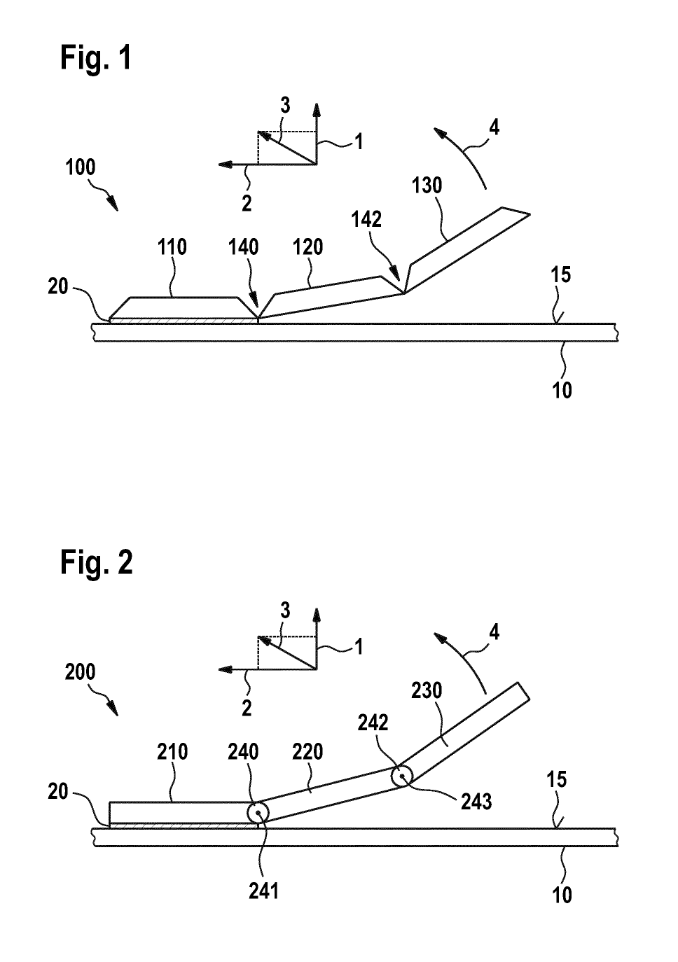

FIG. 1 shows a schematic view of a holding arrangement 100 for holding a substrate 10 during substrate processing in a vacuum processing chamber according to embodiments described herein.

The holding arrangement 100 includes a flexible device having one or more sections. The one or more sections are provided in a first operation condition to have a first portion, a second portion and a curved portion. The curved portion is provided between the first portion and the second portion. The first portion has a surface configured to face the substrate 10. The first portion and the second portion are moveable with respect to each other. An adhesive 20 is provided on the surface of the first portion. In particular, the adhesive 20 is provided between the substrate surface 15 and the surface of the first portion. The first portion, the curved portion and the second portion are sequentially arranged in this order.

The term “flexible device” as used throughout the present disclosure is to be understood in the sense that the flexible device can change its shape so as to perform the rolling motion around a rotational axis substantially parallel to the substrate surface 15. In particular, the term “flexible” is understood to distinguish over “rigid”. In some implementations, the flexibility can be provided by the material of the flexible device. As an example, the flexible device can be made of a single piece of material, such as a metal band described with respect to FIG. 6. In other implementations, the flexibility can be provided by flexible connections, such as hinges, between rigid elements, such as the three or more elements described with reference to FIGS. 1 to 5.

The term “operation condition” is to be understood in the sense of a positioning or shape of the one or more sections of the flexible device, for example, in an attached and detached state. As an example, the first operation condition can be a condition in which the holding arrangement is attached to the substrate. A second operation condition can be a condition in which the holding arrangement is detached from the substrate. The term “operation condition” shall particularly embrace embodiments where the first portion, the second portion and the third portion are not fixedly allocated to specific elements or portions of the flexible device. In other words, at different times or in different conditions, the first portion, the second portion and the third portion can correspond to different portions of the flexible device.

According to some embodiments, which can be combined with other embodiments described herein, the one or more sections are three or more elements flexibly connected to each other. As an example, the three or more elements include a first element 110, a second element 120, and a third element 130. The three or more elements can be rigid. In some implementations, the curved portion is provided by at least one element of the three or more elements. For instance, the first element 110 can provide the first portion, the second element 120 can provide the curved portion, and the third element 130 can provide the second portion. The term “curved portion” is understood as a portion which connects the first portion with the second portion such that the first portion is movable with respect to the second portion. As an example, the curved portion can be provided by one or more straight sections or elements and/or by one or more arched (or bent) sections or elements. The term “curved portion” can be synonymously used with the term “connection portion”.

The three or more elements can be made of a material selected from the group consisting of metals (e.g., steel, stainless steel, copper, aluminum), polymers, plastics and any combination thereof As an example, the flexible device can be a plastic strip on which the adhesive 20, for example, a tape, is fixed.

In some implementations, the three or more elements, such as the first element 110, the second element 120 and the third element 130 are straight elements. The three or more elements can be connected to each other with hinges, such as integral hinges. As an example, the first element 110 and the second element 120 can be connected to each other with a first hinge, such as a first integral hinge 140. The second element 120 and the third element 130 can be connected to each other with a second hinge, such as a second integral hinge 142. In some implementations, the three or more elements can be made of a single piece of material, wherein a material thickness of the single piece can be locally reduced so as to provide the integral hinges. As an example, the flexible device can be an integral hinged plastic strip on which adhesive is fixed by, for example, by glue, clamps, etc. The area of reduced material thickness can have a V-shape. The flexible device has a simple configuration and/or can be manufactured with at least one of reduced effort and reduced costs.

The flexible device rolls the adhesive 20 onto the substrate surface 15 to hold the substrate 10 and rolls the adhesive 20 from the substrate surface 15 to release the substrate 10. The rolling motion (indicated with arrow 4) is a rolling motion around a rotational axis substantially parallel to the substrate surface 15. During the detaching, the rolling motion provides a pulling force or shear force with a vector 3 that is non-parallel with respect to the substrate surface 15. In particular, the vector 3 can have a first vector component 1 perpendicular to the substrate surface 15 and a second vector component 2 parallel to the substrate surface 15. An angle between the substrate surface 15 (or the second vector component 2) and the vector 3 can be less than 90°, specifically less than 60°, and more specifically less than 30°. The adhesive 20 can be detached from the substrate surface 15 with reduced mechanical stress. Damage or breakage of the substrate can be prevented.

According to some embodiments, which can be combined with other embodiments described herein, the adhesive 20 can be an adhesive tape. In some implementations, the adhesive 20 is permanently or removably attached to the surface of the first portion. As an example, the adhesive 20 can be attached to the surface of the first portion using at least one of glue and clamps. In some implementations, the adhesive 20 can be a double-sided adhesive tape. The adhesive capability of the side of the adhesive tape that is attached to the surface of the first portion can be stronger than the adhesive capability of the side of the adhesive tape that is attachable to the substrate surface 15. This prevents the adhesive tape from detaching from the first portion, for example, during the rolling motion for detachment of the holding arrangement from the substrate 10.

According to some embodiments, which can be combined with other embodiments described herein, the adhesive 20 is a synthetic setae material. As an example, the adhesive 20 is a Gecko adhesive, such as a Gecko tape. However, the present disclosure is not limited thereto and other adhesives suitable for holding the substrate 10 can be used.

The adhesive capabilities of the adhesive of the synthetic setae material according to embodiments described herein are related to the adhesive properties of a gecko foot. The natural adhesive capability of the gecko foot allows the animal to adhere to surfaces of many types under most conditions. The adhesive capability of the gecko foot is provided by numerous hair-type extensions, called setae, on the feet of the gecko. It is noted here that the term “synthetic setae material” is to be understood as a synthetic material which emulates the natural adhesive capability of the gecko foot and which includes similar adhesive capabilities to the gecko foot. Moreover, the term “synthetic setae material” may be synonymously used with the term “synthetic gecko setae material” or with the term “gecko tape material”.

The adhesive 20, for example the synthetic setae material, can be inorganic. According to some embodiments described herein, the adhesive 20 is substantially 100% inorganic. Moreover, the microstructure of the adhesive 20 can include nanotubes. According to some embodiments described herein, the microstructure of the adhesive 20 includes carbon nanotubes.

FIG. 2 shows a schematic view of a holding arrangement 200 for holding a substrate 10 during substrate processing in a vacuum processing chamber according to further embodiments described herein. The holding arrangement 200 is similar to the holding arrangement described with reference to FIG. 1, and a description of similar or identical elements is not repeated.

The one or more sections of the flexible device are three or more elements flexibly connected to each other. As an example, the three or more elements include a first element 210, a second element 220, and a third element 230. The three or more elements can be rigid. In some implementations, the curved portion is provided by at least one element of the three or more elements. For instance, the first element 210 can provide the first portion, the second element 220 can provide the curved portion, and the third element 230 can provide the second portion.

In some implementations, the three or more elements can be connected to each other with hinges, such as joints. As an example, the first element 210 and the second element 220 can be connected to each other with a first hinge, such as a first joint 240. The second element 220 and the third element 230 can be connected to each other with a second hinge, such as a second joint 242.

The hinges or joints can provide a respective rotational axis. The elements connected by a hinge or joint can be rotatable with respect to each other around the rotational axis. As an example, the first joint 240 can provide a first rotational axis 241 and the second joint 242 can provide a second rotational axis 243. The first element 210 and the second element 220 can be rotatable with respect to each other around the first rotational axis 241. The second element 220 and the third element 230 can be rotatable with respect to each other around the second rotational axis 243. The rotational axes of the hinges can be parallel to the rotational axis of the rolling motion. The flexible device having the hinges has a simple and stable configuration.

The three or more elements, such as the first element 210, the second element 220 and the third element 230 can be straight elements. According to some embodiments, which can be combined with other embodiments described herein, the three or more elements can be chain links. The chain links can provide a chain, for example, a drag chain.

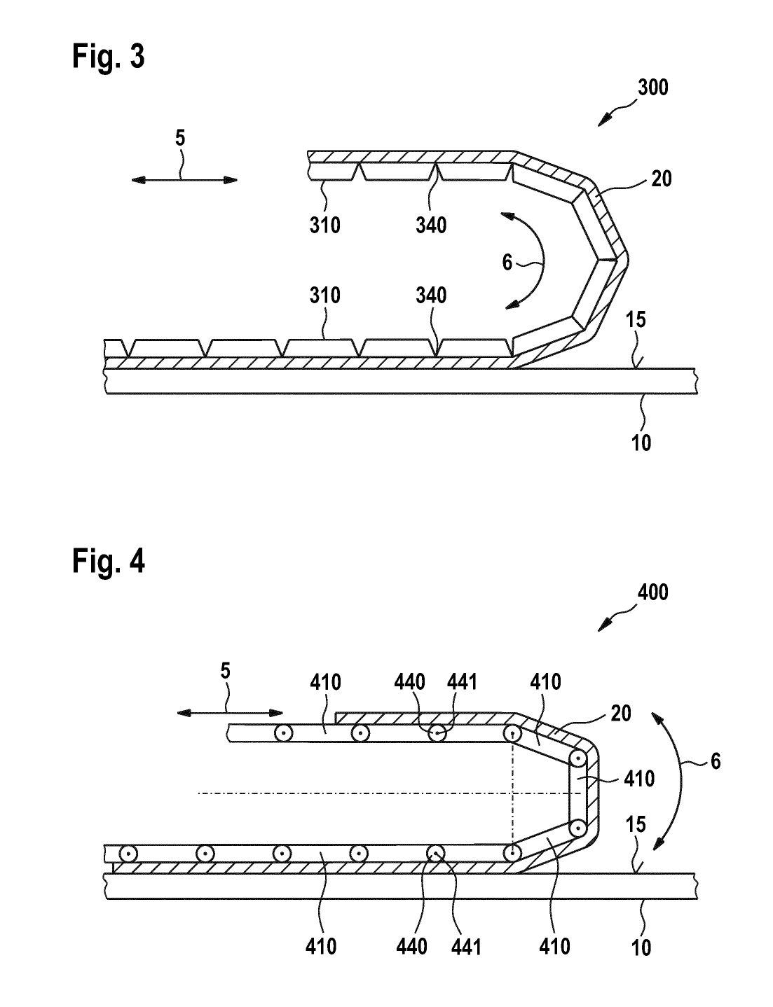

FIG. 3 shows a schematic view of yet another holding arrangement 300 for holding a substrate during substrate processing in a vacuum processing chamber according to embodiments described herein.

The holding arrangement 300 has three or more elements 310 flexibly connected to each other with hinges 340, such as integral hinges. The three or more elements 310 provide the first portion, the second portion and the third portion. The adhesive 20 is provided at least on the surface of the first portion, for example, the surface of one or more elements of the three or more elements 310 such as two or more elements of the three or more elements 310. In some implementations, as shown in FIG. 3, the adhesive 20 can be provided on a surface of at least one further portion, such as the second portion and/or the third portion.

According to some embodiments, which can be combined with other embodiments described herein, the first portion and the second portion can be substantially parallel to each other. The first portion and the second portion are connected by the curved portion, which can be provided by one or more elements of the three or more elements 310. The term “substantially parallel” relates to a substantially parallel orientation e.g. of the first portion and second portion, wherein a deviation of a few degrees, e.g. up to 10° or even up to 20°, from an exact parallel orientation is still considered as “substantially parallel”.

Adjacent surfaces of the first portion and the second portion, such as adjacent surfaces of one or more elements 310 of the first portion and one or more elements 310 of the second portion can have a distance therebetween. The distance can define a radius of the rolling motion 6. Specifically, the distance can be twice the radius of the rolling motion 6. In some implementations, the distance can define a radius of the curved portion. Specifically, the distance can be twice the radius of the curved portion. According to some embodiments, the distance can be at least 1 cm, specifically at least 3 cm, and more specifically at least 5 cm.

The first portion and the second portion are movable with respect to each other (indicated with arrow 5). In some embodiments, the first portion and the second portion are movable respect to each other substantially parallel to the substrate surface 15. As an example, the first portion, which can be attached to the substrate surface 15, can be fixed in position. The second portion can be movable, for example, substantially parallel to the substrate surface 15. The rolling motion 6, such as the first rolling motion and the second rolling motion, is provided by the relative movement between the first portion and the second portion. As an example, to detach the adhesive 20 from the substrate 10, one end of the flexible device, such as an end of the second portion, can be pulled and the flexible device is rolled away from the substrate 10.

It is noted that, during the rolling motion 6 (second rolling motion) for detaching the holding arrangement from the substrate, at least a part of the initially present first portion can be transferred into the curved portion and optionally into the second portion. Similarly, at least a part of the initially present curved portion can be transferred into the second portion. Likewise, during the rolling motion 6 (first rolling motion) for attaching the holding arrangement to the substrate, at least a part of the initially present second portion can be transferred into the curved portion and optionally into the first portion. Similarly, at least a part of the initially present curved portion can be transferred into the first portion.

According to some embodiments, which can be combined with other embodiments described herein, the holding arrangement includes an actuator (not shown) configured to move the first portion and the second portion with respect to each other to provide the rolling motion. The actuator can be a manual actuator or an automatic actuator. The automatic actuator can include at least one motor, such as an electric motor, a pneumatic motor and/or a stepper motor.

FIG. 4 shows a schematic view of a holding arrangement 400 for holding a substrate 10 during substrate processing in a vacuum processing chamber according to yet further embodiments described herein. The holding arrangement 400 is similar to the holding arrangements described with reference to FIGS. 2 and 3, and a description of similar or identical elements is not repeated. The holding arrangement 400 includes more elements 410 connected to each other with hinges 440, such as joints, providing respective rotational axes 441.

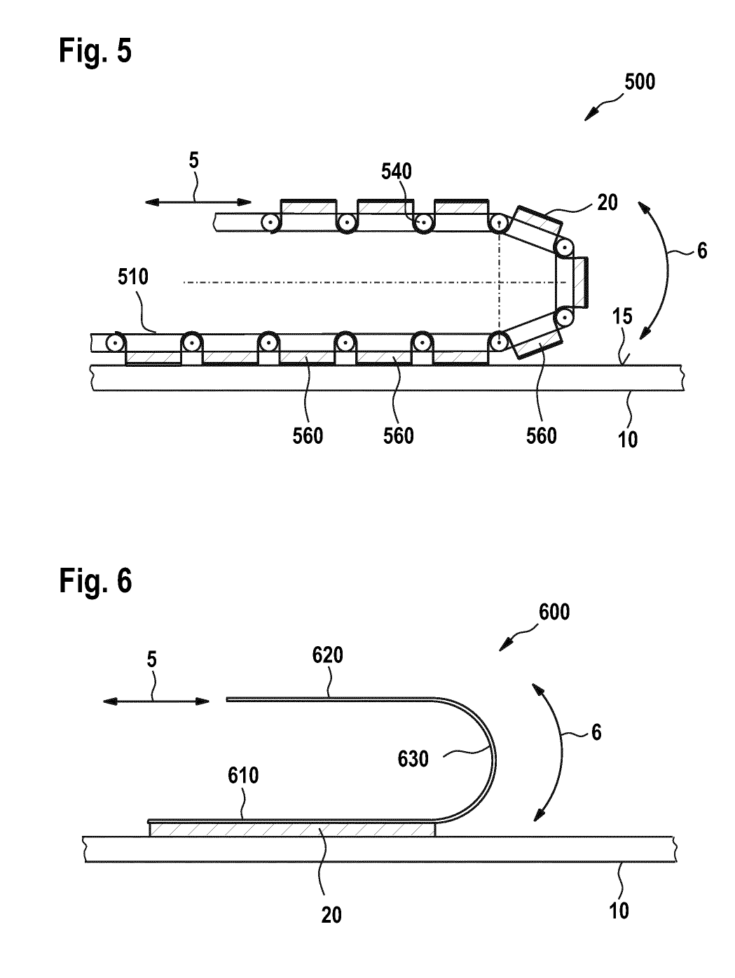

FIG. 5 shows a schematic view of a holding arrangement 500 for holding a substrate 10 during substrate processing in a vacuum processing chamber according to further embodiments described herein. The holding arrangement 500 is similar to the holding arrangement described with reference to FIG. 4, and a description of similar or identical elements is not repeated.

According to some embodiments, which can be combined with other embodiments described herein, the adhesive 20 is an adhesive tape. The adhesive tape can be wound around at least some of the hinges 540. As an example, the adhesive tape can be woven on the chain provided by the three or more elements 510 which can be chain links. In some implementations, the holding arrangement 500 can include support surfaces configured for supporting the adhesive tape. As an example, at least some of the three or more elements 510 can include respective support surfaces 560 on which the adhesive tape rests.

In some embodiments, the adhesive tape can have its ends fixed on the holding arrangement 500, for example, the flexible device. According to some embodiments, which can be combined with other embodiments described herein, the ends of the adhesive tape can be fixed on the holding arrangement using at least one of glue and clamps. For instance, a first end of the adhesive tape can be fixed to the first portion, and a second end of the adhesive tape can be fixed to the second portion. In some embodiments, the adhesive tape can be loosely positioned (not fixed) on the support surfaces 560.

FIG. 6 shows a schematic view of a holding arrangement 600 for holding a substrate 10 during substrate processing in a vacuum processing chamber according to yet further embodiments described herein.

The holding arrangement 600 includes a flexible device having only one section. The flexible device can be a band, such as a continuous band. The one section is provided in a first operation condition to have a first portion 610, a second portion 620 and a curved portion 630. The curved portion 630 is provided between the first portion 610 and the second portion 620. The first portion 610 has a surface configured to face the substrate 10. The first portion 610 and the second portion 620 are moveable with respect to each other (indicated with arrow 5). An adhesive 20 is provided on the surface of the first portion 610.

The flexibility of the flexible device is provided by the material of the flexible device. As an example, the flexible device can be made of a single piece of material, such as a flexible band or continuous flexible band. In particular, the curved portion 630 can be provided by a curved section of the flexible band. The material of the flexible device can select from the group consisting of metals (e.g., steel, stainless steel, copper, aluminum), polymers, plastics, and any combination thereof. As an example, the flexible band can be a metal band. In some embodiments, a width of the flexible band can be at least 1 cm, specifically at least 3 cm, and more specifically at least 5 cm. Additionally or alternatively, the width can be less than 10 cm. The flexible device has a simple configuration and/or can be manufactured with at least one of reduced effort and reduced costs.

During the rolling motion 6 (the second rolling motion) for detaching the holding arrangement 600 from the substrate 10, at least a part of the initially present first portion 610 can be transferred into the curved portion 630 and optionally into the second portion 620. Similarly, at least a part of the initially present curved portion 630 can be transferred into the second portion 620. Likewise, during the rolling motion 6 (the first rolling motion) for attaching the holding arrangement 600 to the substrate, at least a part of the initially present second portion 620 can be transferred into the curved portion 630 and optionally into the first portion 610. Similarly, at least a part of the initially present curved portion 630 can be transferred into the first portion 610.

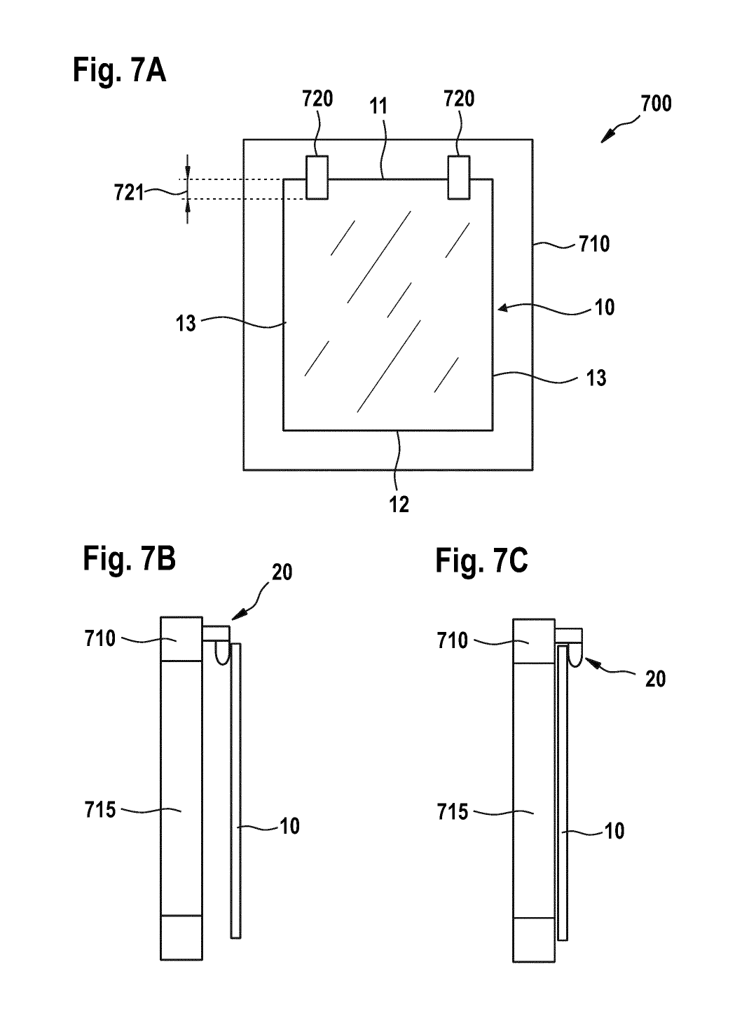

FIGS. 7A-C show schematic views of a carrier 700 for supporting a substrate 10 in a vacuum processing chamber according to embodiments described herein. FIG. 7A shows a plan view. FIGS. 7B and C show cross-sectional side views.

The carrier 700 includes at least one flexible device at least partially covered with an adhesive, such as an adhesive layer, for removably attaching the flexible device to the substrate. In some implementations, the carrier 700 includes a carrier body 710 and one or more holding arrangements 720 having the flexible device and mounted on the carrier body 710. The one or more holding arrangements 720 can be configured according to the embodiments described herein. The one or more holding arrangements 720 are configured for holding the substrate 10 at the carrier body 710. Specifically, the one or more holding arrangements 720 can use a holding force to hold the substrate 10. The holding force can be substantially parallel to the substrate surface, specifically when the substrate 10 is in a substantially vertical orientation. The holding force is provided by the adhesive of the holding arrangement.

The carrier 700 is configured to support the substrate 10 during substrate processing, for example, during a layer deposition process, such as a sputtering process. The carrier body 710 can include, or be, a plate or a frame configured for contacting and/or supporting the substrate 10, for example, using a surface provided by the plate or frame. The carrier body 710 can be made of aluminum, aluminum alloys, titanium, alloys thereof, stainless steel or the like. According to some embodiments, which can be combined with other embodiments described herein, the carrier body 710 can include two or more elements such as a top bar, sidebars and a bottom bar. The two or more elements can define an aperture opening 715. In some implementations, a masking device is provided at the carrier 700 to mask one or more portions of the substrate 10. As an example, the masking device can be an edge exclusion mask.

The substrate 10 has a first surface and a second surface. The first surface can be a backside surface of the substrate 10. As an example, the first surface can be configured to face towards the carrier body 710. The second surface can be a front surface of the substrate 10. The second surface can be a surface of the substrate 10 which is to be processed in the vacuum processing chamber. As an example, the second surface can be configured for layer deposition thereon. According to some embodiments, which can be combined with other embodiments described herein, the adhesive 20 is configured to contact the first surface (FIG. 7B) or the second surface (FIG. 7C) of the substrate 10. As an example, the adhesive 20 is configured to contact the first surface of the substrate 10. A contact with the second surface, e.g., a deposition surface of the substrate 10 can be reduced or avoided. A uniformity of a layer during a deposition process can be improved.

According to some embodiments, which can be combined with other embodiments described herein, the carrier 700 is configured for holding or supporting the substrate 10 in a substantially vertical orientation, e.g., during a layer deposition process. As an example, the one or more holding arrangements 720 can be configured to hold the substrate 10 in the substantially vertical orientation. As used throughout the present disclosure “substantially vertical” is understood particularly when referring to the substrate orientation, to allow for a deviation from the vertical direction or orientation of ±20° or below, e.g. of ±10° or below. This deviation can be provided for example because a substrate support with some deviation from the vertical orientation might result in a more stable substrate position. Yet, the substrate orientation, e.g., during the layer deposition process, is considered substantially vertical, which is considered different from the horizontal substrate orientation.

The substrate 10 has an upper side 11, a lower side 12 and two lateral sides 13 (e.g., a left side and a right side). The upper side 11, the lower side 12 and the two lateral sides 13 can be defined with respect to a vertical orientation of the substrate 10. Likewise, the carrier 700 or carrier body 710 has an upper side, a lower side and two lateral sides (e.g., a left side and a right side).

In some implementations, the one or more holding arrangements 720 are mounted on the carrier body 710 to hold at least one of the upper side 11, the lower side 12, and at least one of the two lateral sides 13 of the substrate 10. As an example, one or more holding arrangements 720 (e.g., two holding arrangements) are provided to hold the upper side 11 and/or one or more holding arrangements 720 (e.g., two holding arrangements) are provided to hold the lower side 12 and/or two or more holding arrangements 720 are provided to hold each side of the two lateral sides 13 (e.g., two holding arrangements for the left side and two holding arrangements for the right side).

According to some embodiments, the one or more holding arrangements 720 are mounted on the carrier body 710 to hold the substrate 10 suspended. Specifically, the one or more holding arrangements 720 are configured to hold the upper side 11 of the substrate 10. In some implementations, the substrate 10 is only held at the upper side 11. As an example, the carrier 700 includes one or more holding arrangements 720 (e.g., two holding arrangements) only at the upper side of the carrier body 710 to hold the upper side 11 of the substrate 10.

The holding arrangement, and specifically the first portion of the holding arrangement, extends a distance 721 over the substrate surface. The distance 721 can be measured from a periphery or edge of the substrate 10 in a direction parallel to the substrate surface. The distance 721 can be less than 7 cm, specifically less than 5 cm, and more specifically less than 3 cm.

The holding arrangement, and specifically the first portion of the holding arrangement, has a width. The width can be measured in a direction parallel to the rotational axis of the rolling motion and/or parallel to the rotational axes provided by the hinges of the holding arrangement. The width of the first portion can correspond to a width of the adhesive such as the adhesive tape. The width can be at least 1 cm, specifically at least 3 cm, and more specifically at least 5 cm. At least one of the distance 721 and the width can be selected based on a holding force needed to hold the substrate 10, for example, in the vertical orientation.

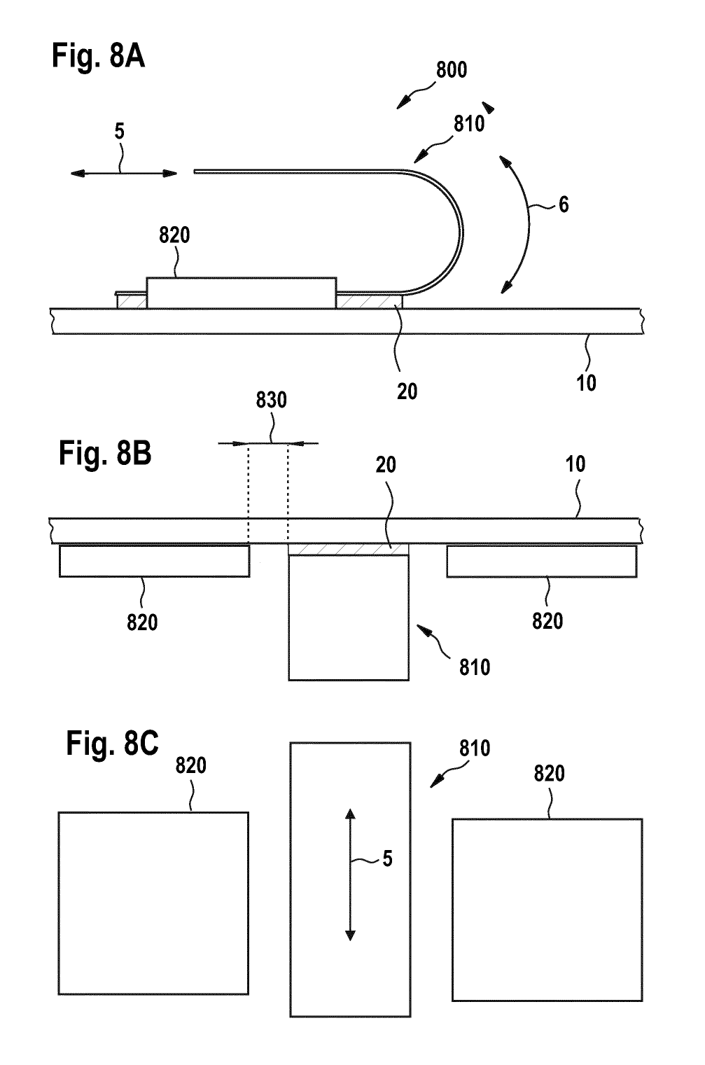

FIGS. 8A-C show schematic views of a holding arrangement 800 for holding a substrate during substrate processing in a vacuum processing chamber according to further embodiments described herein. FIG. 8A shows a cross-sectional side view. FIG. 8B shows a top view. FIG. 8C shows the plan view.

According to some embodiments, which can be combined with other embodiments described herein, the holding arrangement 800 includes one or more contact elements 820 configured to contact the surface of the substrate 10, such as the first surface or backside surface. The one or more contact elements 820 can support the substrate 10, for example, during the rolling motion. The rolling motion for detaching and/or attaching the adhesive 20 on the substrate 10 can be provided more stably. Damage of the substrate 10 during the rolling motion can be avoided.

In some implementations, the one or more contact elements 820 are provided adjacent to the flexible device 810. As an example, one or more contact elements 820 are provided on each side of the flexible device 810. In some implementations, at least one first contact element is provided at a first side of the flexible device 810 and at least one second contact element is provided at a second side of the flexible device 810. The first side and the second side of the flexible device 810 can be opposing sides. In other words, the flexible device 810 can be provided between the at least one first contact element and the at least one second contact element.

According to some embodiments, a distance 830 between the flexible device 810 and the one or more contact elements 820 can be such that the rolling motion can be performed without interference. As an example, the distance 830 can be selected as small 25 as possible. The distance 830 can be less than 5 cm, specifically less than 1 cm, and more specifically less than 0.5 cm.

In some embodiments, the one or more contact elements 820 have an extension or length in a direction parallel to the direction of the rolling motion. The direction of the rolling motion can correspond to the moving direction of the first portion and the second portion, which is indicated with arrow 5. The extension or length of the one or more contact elements 820 can be equal to, or less than, a contact length between the adhesive 20 and substrate 10 in the attached state. As an example, the extension or length of the one or more contact elements 820 can be approximately the same length as the contact length.

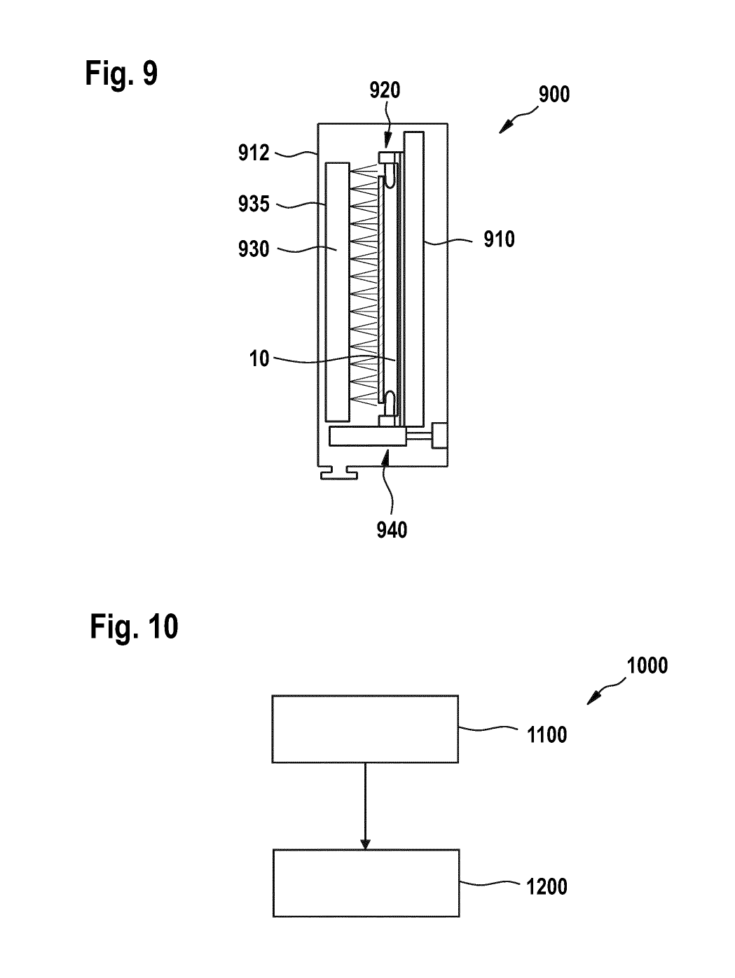

FIG. 9 shows a schematic view of a deposition system 900 according to embodiments described herein.

The deposition system 900 includes a vacuum processing chamber 912, such as a deposition chamber adapted for a deposition process. The deposition process can be a PVD or CVD process. A carrier 910 has the substrate 10 positioned thereon. The carrier 910 is configured according to the embodiments described herein and has one or more holding arrangements 920. The carrier 910 is shown being located within or at a support on a substrate transportation device 940.

A deposition material source 930 is provided in the vacuum processing chamber 912 facing the side of the substrate 10 to be coated. The deposition material source 930 provides deposition material 935 to be deposited on the substrate 10. The deposition material source 930 may be a target with deposition material thereon or any other arrangement allowing material to be released for deposition on the substrate 10. In some implementations, the deposition material source 930 may be a rotatable target. According to some embodiments, the deposition material source 930 may be movable in order to position and/or replace the deposition material source 930. According to other embodiments, the deposition material source 930 may be a planar target.

According to some embodiments, the deposition material 935 may be chosen according to the deposition process and the later application of the coated substrate. For instance, the deposition material of the deposition material source 930 may be a material selected from the group consisting of: a metal, such as aluminum, molybdenum, titanium, copper, or the like, silicon, indium tin oxide, and other transparent conductive oxides. Oxide-, nitride- or carbide-layers, which can include such materials, can be deposited by providing the material from the deposition material source 930 or by reactive deposition, i.e. the material from the deposition material source 930 reacts with elements like oxygen, nitride, or carbon from a processing gas.

A carrier according to embodiments described herein can be beneficial for stationary processes and also for non-stationary processes. The carrier can hold the substrate 10 in a substantially vertical orientation.

FIG. 10 shows a flow chart of a method 1000 for holding a substrate according to embodiments described herein. The method 1000 can utilize the holding arrangements and carriers according to the embodiments described herein. Likewise, the holding arrangements and carriers can be configured to implement the method 1000 according to the embodiments described herein.

The method 1000 includes in block 1100 a performing of a first rolling motion of a flexible device of a holding arrangement around a rotational axis parallel to a substrate surface to bring an adhesive on a first portion of the flexible device in contact with the substrate surface. The first rolling motion allows for attaching the holding arrangement to the substrate in order to hold the substrate, for example, in a substantially vertical orientation.

In some implementations, the method 1000 includes in block 1200 a performing of a second rolling motion of the flexible device around the rotational axis to release the contact between the adhesive and the substrate surface. The second rolling motion allows for detaching the holding arrangement from the substrate in order to release the substrate, for example, for subsequent processing.

The first rolling motion can be a rolling motion around the rotational axis in a first direction. The second rolling motion can be a rolling motion around the rotational axis and a second direction opposite the first direction. As an example, the first direction can be a clockwise direction and the second direction can be a counterclockwise direction. In another example, the first direction can be a counterclockwise direction and the second direction can be a clockwise direction.

According to an aspect of the present disclosure, a method for holding a substrate is provided. The method includes providing a carrier comprising at least one flexible device at least partially covered with an adhesive such as an adhesive layer, attaching the substrate to the carrier by attaching the adhesive to the substrate, moving the carrier with the substrate through a vacuum processing chamber, and detaching the substrate from the carrier by peeling the adhesive off the substrate. The carrier and the flexible device can be configured according to the embodiments described herein. In particular, the flexible device can be included in the holding arrangement of the present disclosure.

According to embodiments described herein, the method for holding a substrate can be conducted by means of computer programs, software, computer software products and the interrelated controllers, which can have a CPU, a memory, a user interface, and input and output means being in communication with the corresponding components of the apparatus for processing a large area substrate.

The present disclosure uses a flexible device to “roll” the adhesive onto (first rolling motion) and off of (second rolling motion) the substrate. In particular, the flexible device rolls the adhesive onto the substrate surface in the first rolling motion to hold the substrate and rolls or peels the adhesive off of the substrate surface in the second rolling motion to release the substrate. During the detachment, the rolling motion provides a pulling force or shear force with a vector that is non-parallel with respect to the substrate surface. The adhesive can be detached from the substrate surface with reduced mechanical stress. Damage or breakage of the substrate can be prevented. Further, the adhesive can reduce or even avoid a bulging when holding the substrate, e.g., a bulging due to forces that may push the substrate edge towards the center of the substrate. In particular, the embodiments of the present disclosure can hold bigger and thinner substrates without damage or breakage.

While the foregoing is directed to embodiments of the disclosure, other and further embodiments of the disclosure may be devised without departing from the basic scope thereof, and the scope thereof is determined by the claims that follow.

1. A holding arrangement for holding a substrate during substrate processing in a vacuum processing chamber, comprising:
a flexible device having one or more sections, wherein the one or more sections are provided in a first operation condition to have a first portion, a second portion and a curved portion, wherein the curved portion is provided between the first portion and the second portion, wherein the first portion has a surface configured to face the substrate, and wherein the first portion and the second portion are moveable with respect to each other; and
an adhesive provided on the surface of the first portion.

2. The holding arrangement of claim 1, wherein the one or more sections are three or more elements flexibly connected to each other.

3. The holding arrangement of claim 2, wherein the three or more elements are connected to each other with hinges.

4. The holding arrangement of claim 3, wherein the adhesive is an adhesive tape, and wherein the adhesive tape is wound around at least some of the hinges.

5. The holding arrangement of claim 2, wherein the three or more elements are at least one of straight elements and chain links.

6. The holding arrangement of claim 2, wherein the curved portion is provided by at least one element of the three or more elements.

7. The holding arrangement of claim 2, wherein the three or more elements are rigid.

8. The holding arrangement of claim 1, wherein the one or more sections are one section provided by a flexible band.

9. The holding arrangement of claim 8, wherein the curved portion is provided by a curved section of the flexible band.

10. The holding arrangement of claim 1, wherein the adhesive is a synthetic setae material.

11. Carrier for supporting a substrate in a vacuum processing chamber, comprising:
a carrier body; and
one or more holding arrangements, the holding arrangement comprising:
a flexible device having one or more sections, wherein the one or more sections are provided in a first operation condition to have a first portion, a second portion and a curved portion, wherein the curved portion is provided between the first portion and the second portion, wherein the first portion has a surface configured to face the substrate, and wherein the first portion and the second portion are moveable with respect to each other; and an adhesive provided on the surface of the first portion, wherein the one or more holding arrangements are mounted on the carrier body.

12. The carrier of claim 11, wherein the one or more holding arrangements are mounted on the carrier body to hold the substrate suspended.

13. Carrier for supporting a substrate in a vacuum processing chamber, comprising:
at least one flexible device at least partially covered with an adhesive for removably attaching the flexible device to the substrate.

14. The carrier of claim 11, wherein the carrier is configured to hold the substrate in a vertical orientation.

15. Method for holding a substrate, comprising:
performing a first rolling motion of a flexible device of a holding arrangement around a rotational axis parallel to a substrate surface to bring an adhesive on a first portion of the flexible device in contact with the substrate surface.

16. The method of claim 15, further comprising:
performing a second rolling motion of the flexible device around the rotational axis to release the contact between the adhesive and the substrate surface.

17. Method for holding a substrate, comprising:
providing a carrier comprising at least one flexible device at least partially covered with an adhesive;
attaching the substrate to the carrier by attaching the adhesive to the substrate;
moving the carrier with the substrate through a vacuum processing chamber; and
detaching the substrate from the carrier by peeling the adhesive off the substrate.

18. The holding arrangement according to claim 1, wherein the holding arrangement is configured to hold a large area substrate in a substantially vertical orientation during substrate processing in the vacuum chamber.

19. The holding arrangement of claim 18, wherein the adhesive is a synthetic setae material.

20. The carrier of claim 13, wherein the carrier is configured to hold the substrate in a vertical orientation.
